(19) United States
(12) Patent Application Publication
(10) Pub. No.: US 2007/0267173 A1
(43) Pub. Date: Nov. 22, 2007

(54) Radiator for heat sink device

(75) Inventors: Jing-De Gu, Hsin-Chuang (TW); Jiang-Yan Liu, Hsin-Chuang (TW); Hsin-Cheng Lin, Hsin-Chuang (TW)

Correspondence Address: Asia Vital Components Co., Ltd., P.O BOX 1-195, YUNG HO, omitted

(73) Assignee: ASIA VITAL COMPONENTS CO., LTD., HSIN-CHUANG (TW)

(21) Appl. No.: 11/437,509

(22) Filed: May 22, 2006

(51) Int. Cl. H05K 7/20

(52) U.S. Cl. 165/80.3; 361/704; 257/720

(57) ABSTRACT

A radiator for a heat sink device is formed by an extruded aluminum. The radiator comprises a base and a heat conductive metallic element. The base has a plurality of fins on a side and at least an indentation on another side. The heat conductive metallic element corresponds to the indentation. The inner sidewall of the indentation and the heat conductive metallic element correspond to at least one surface of the inner sidewall of the indentation. The inner sidewall of the indentation and the heat conductive metallic element comprise chambers for receiving jointing material for jointing the heat conductive metallic element to the indentation.

### BACKGROUND OF THE INVENTION

1. Field of the Invention

The present invention generally relates to a radiator for a heat sink device, and more particularly to a radiator with a heat conductive metallic element.

2. Description of the Related Art

Conventional radiator for the heat sink device comprises a main structure, and a plurality of fins disposed on a top side and an indentation at a bottom side thereof. To joint the heat conductor to the indentation of the main structure, the indentation is heated first to expand or enlarge the indentation for inlaying the room temperature heat conductor and then cooled down to tightly joint the heat conductor within indentation of the main structure. Consequently, this process is a laborious and time consuming process. By contacting a side of the heat conductor exposed by the indented groove to the heating element, for example, a CPU of a computer, the heat generated by the heating element can be conducted and dissipated.

The above conventional radiator has the heat conductor tightly fitted into the indentation, and therefore the roughness and the size of the inner surface of the indented groove and the outer surface of the heat conductor must be identical and precise, otherwise the heat dissipation effect would be adversely affected due to formation of a gap there-between during the jointing process. This would not only increase the manufacturing cost but also reduces the yield.

Another conventional radiator has a tin material disposed between the indented groove and the heat conductive element, where the tin material is melted and then filled between the indented groove and the heat conductive element to securely position the heat conductive element in the indented groove. However, because the heat conductive element is tightly jointed to the indented groove by the melted tin material, and therefore in case of defect in jointing the heat conductive element to the indented groove, the melted tin material can not be removed to repair the defect, and the poor attachment of the indented groove and the heat conductive element would substantially affect the heat dissipation efficiency of the heat sink device.

Accordingly, the present inventor provides a radiator for a heat sink device with a better heat dissipation efficiency.

### SUMMARY OF THE INVENTION

Accordingly, in the view of the foregoing, the present invention provides a radiator for a heat sink device, which comprises a heat conductive metallic element loosely positioned in the indented groove of the radiator. A jointing material is disposed between the indented groove and the heat conductive metallic element, and between both or one of the storage chambers of an inner sidewall of the indented groove and an outer surface of the heat conductive metallic element. Thus, the jointing material can be properly positioned in the indented groove or the heat conductive metallic element to adhere the heat conductive metallic element in the indented groove without any gap there-between.

According to another aspect of the present invention, the heat conductive metallic element is loosely adhered to the indented groove to increase the throughput and yield, and thereby reduce the overall manufacturing cost.

The radiator of the present invention device comprises a base comprising at least a first side and a second side positioned apart from the first side. The first side comprises a plurality of fins. The second side comprises at least one indentation facing towards the inner side of the base. The indentation comprises at least a storage chamber at the inner sidewall. The heat conductive metallic element comprises at least a storage chamber positioned at an outer surface corresponding to the inner sidewall of the indentation. A jointing material is disposed in the storage chamber and is adopted for securely adhering the heat conductive metallic element and the indented groove by subjecting the radiator and the jointing material to a heating process.

### BRIEF DESCRIPTION OF THE DRAWING

For a more complete understanding of the present invention, reference will now be made to the following detailed description of preferred embodiments taken in conjunction with the following accompanying drawings.

FIG. 1 is an exploded view of a radiator according to a first embodiment of the present invention.

FIG. 2 is perspective view of the radiator according to the first embodiment of the present invention.

FIG. 3 is perspective top view of the radiator according to the first embodiment of the present invention.

FIG. 4 is an exploded view of a radiator according to a second embodiment of the present invention.

FIG. 5 is a perspective top view of the radiator according to the second embodiment of the present invention.

FIG. 6 is an exploded view of the radiator according to the second embodiment of the present invention.

FIG. 7 is perspective top view of the radiator according to the second embodiment of the present invention.

FIG. 8 is perspective front view of the radiator according to the second embodiment of the present invention.

FIG. 9 is another perspective front view of the radiator according to the second embodiment of the present invention.

### DETAILED DESCRIPTION OF THE EMBODIMENTS

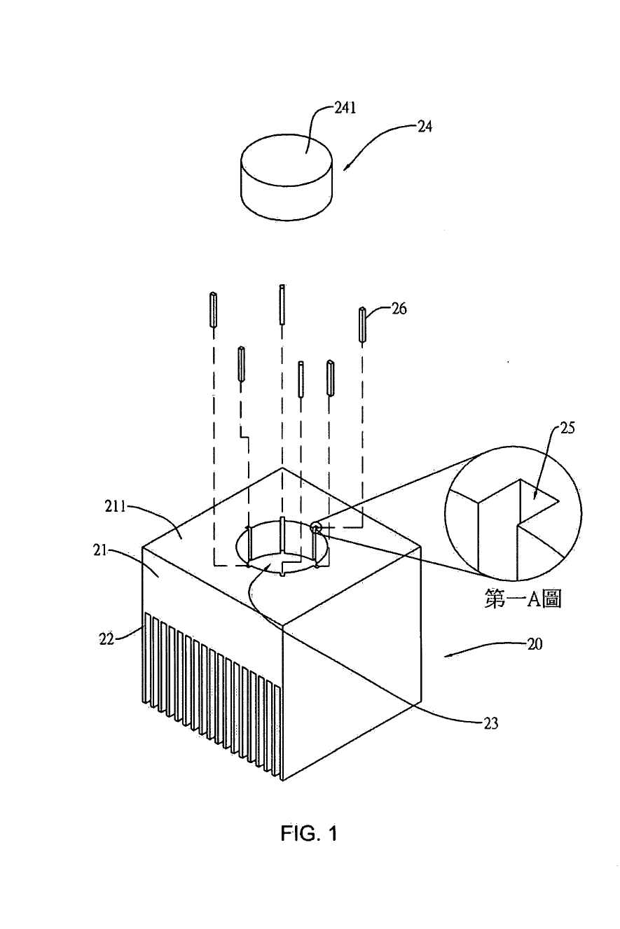

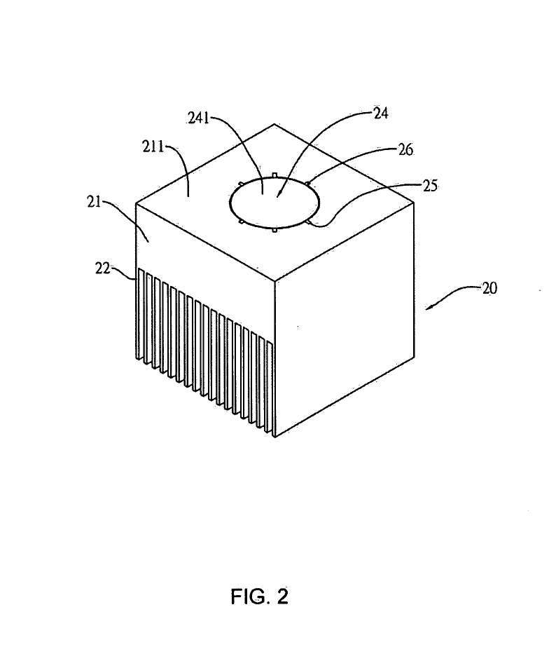

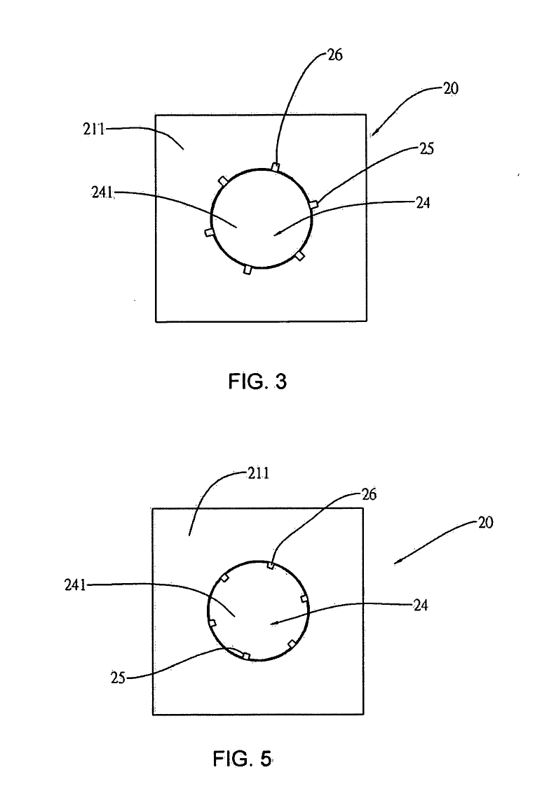

The radiator, according to the first embodiment of the present invention is fabricated via an aluminum extrusion process. Referring to FIGS. 1, 1A, 2 and 3, the radiator 20 comprises a base 21 comprising at least a first side and a second side 211 apart from the first side. The first side comprises an alternately positioned and spaced apart plurality of fins 22, and the second side 211 comprises at least an indentation 23 facing towards the inner side of the base 21. In this embodiment, the indentation 23 is not connected to the flange of the base 21. In other words, the flange of the indentation 23 is apart from the flange of the base 21.

A heat conductive metallic element 24 is disposed corresponding to the above indentation 23, and the shape of the heat conductive metallic element 24 is the same as that of the indentation 23 but the size of the heat conductive metallic element 24 is slightly smaller than the indentation 23 such that the heat conductive metallic element 24 can be loosely positioned in the indentation 23, and thereby facilitating assembly thereof. Furthermore, the heat conductive metallic element 24 comprises another side 241, which does not correspond to the inner sidewall of the indentation 23 and is exposed out of the base 21.

The above indentation 23 comprises at least an inner sidewall corresponding to at least one outer surface of the heat conductive metallic element 24, wherein both or anyone of the inner sidewall and the outer surface of the heat conductive metallic element 24 have at least one storage chamber. The accompanying figures show that the inner sidewall of the indentation 23 comprises a plurality of storage chambers 25 (as shown in FIG. 1A) for receiving at least a jointing material 26.

The jointing material 26 may be disposed into the storage chamber 25 before or after the heat conductive metallic element 24 is positioned into the indentation 23 such that the jointing material 26 is positioned between the heat conductive metallic element 24 and the indentation 23. The jointing material 26 is subjected a thermal process to adhere the heat conductive metallic element 24 to the indentation 23. The jointing material 26 comprises, for example, solid tin (also known as tin bar), liquefied tin or semi-solid tin (also known as tin paste), or any other suitable jointing materials.

The above base 21 and the heat conductive metallic element 24 may be fabricated using the same or different metallic materials. The metallic material may be selected from a group consisting of gold, silver, copper, aluminum, or alloys thereof. If the base 21 is comprised of aluminum, the heat conductive metallic element 24 may be comprised of copper for its excellent heat conduction property.

When the base 21 with the heat conductive metallic element 24 is passed through the furnace, the jointing material 26 disposed in the storage chamber 25 melts and fills the gap between the indentation 23 and the heat conductive metallic element 24. After the jointing material 26 cools down, the heat conductive metallic element 24 is secured in the indentation 23.

Because the heat conductive metallic element 24 is loosely positioned in the indentation 23, the size and the surface roughness of the heat conductive metallic element 24 and the indentation 23 need not be precise. Thus, the throughput can be substantially increased and also the overall manufacturing cost can be reduced. Furthermore, the disadvantage of the conventional radiator due to poor heat conduction effect may be overcome by securing the heat conductive metallic element 24 to the indentation 23 using the jointing material 26. Thus, not only the heat conduction from the heat conductive metallic element 24 to the base 21 is improved but also the yield is increased.

Referring FIG. 4, the indentation 23 comprises a corrugated surface 27 for facilitating the jointing material 26 to quickly and uniformly fill between the indentation 23 and the heat conductive metallic element 24. The corrugated surface 27 shown in the indentation 23 in the accompanying figures is not intended for limiting the scope of the present invention. The corrugated surface 27 may be formed on the surface of the indentation 23 and the storage chamber 25, or corrugated surface 27 may be formed on the outer surface of the indentation 23 corresponding to the heat conductive metallic element 24. The corrugated surface 27 effectively increases the contact surface area between the indentation 23 and the heat conductive metallic element 24 and thereby promotes the heat conduction effect.

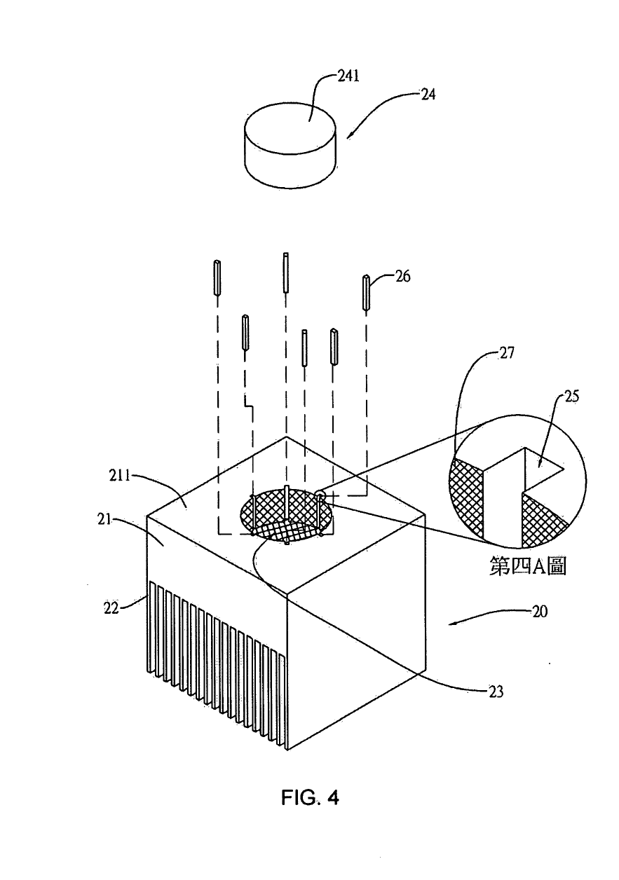

Referring to FIG. 5, according to another aspect of the present invention, the storage chamber 25 is formed on the outer surface of the inner sidewall of the indentation 23 corresponding to the heat conductive metallic element 24, and the result is the same as described above.

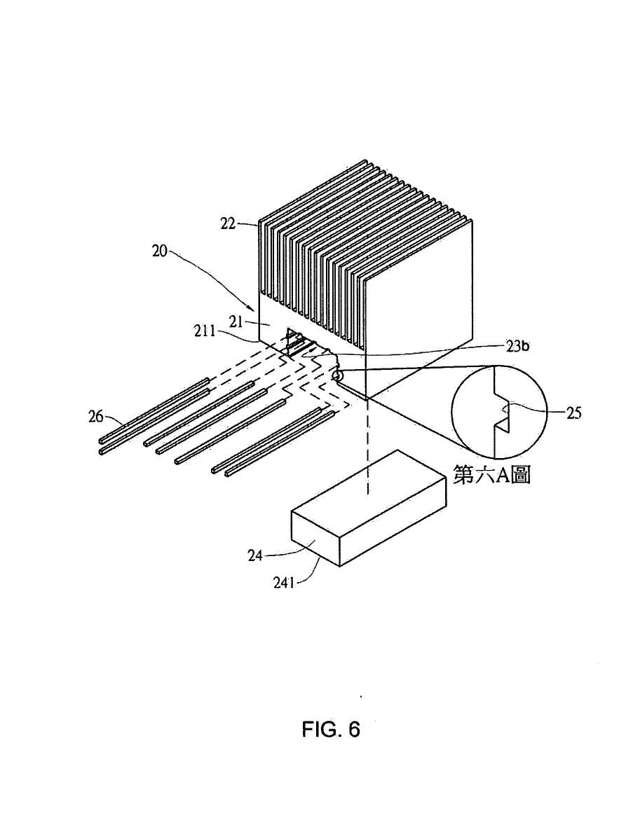

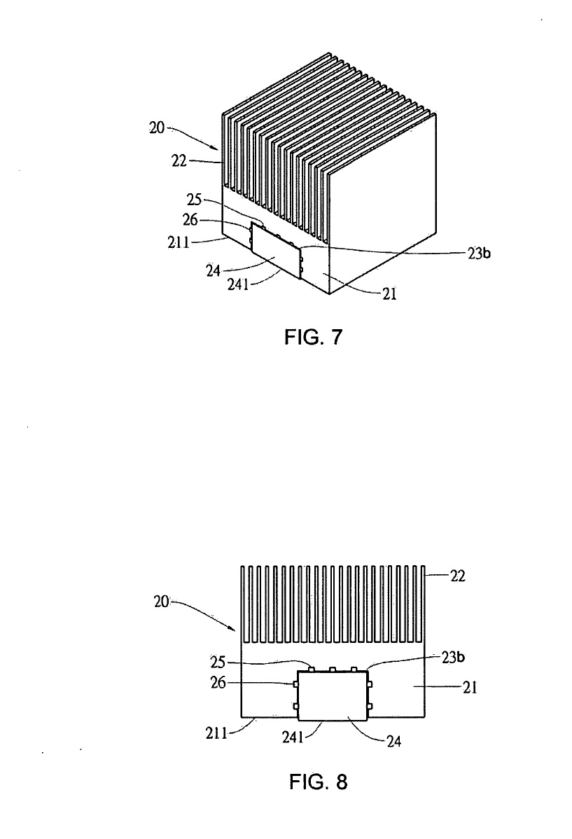

The radiator according to the second embodiment of the present invention illustrated by FIGS. 6, 6A, 7 and 8 is similar to that of the first embodiment described above except for the indentation 23b is connected to the flange of the base 21.

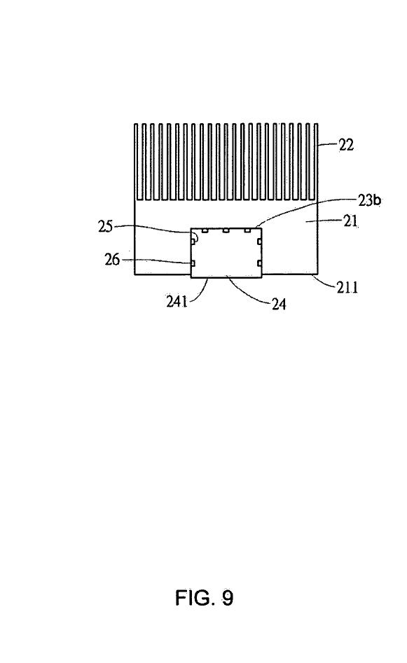

Referring to FIG. 9, according to another aspect of the present invention, the storage chamber 25 is formed on the outer surface of the inner sidewall of the indentation 23 corresponding to the heat conductive metallic element 24, and the result is the same as described above.

The above described corrugated surface 27 may have an interlacing pattern, as shown in the figure, or non-interlacing pattern (not shown).

While the invention has been described in conjunction with a specific best mode, it is to be understood that many alternatives, modifications, and variations will be apparent to those skilled in the art in light of the foregoing description. Accordingly, it is intended to embrace all such alternatives, modifications, and variations in which fall within the spirit and scope of the included claims. All matters set forth herein or shown in the accompanying drawings are to be interpreted in an illustrative and non-limiting sense.

1. A radiator, for a heat sink device, comprising
a base, comprising at least a first side and a second side apart from said first side, wherein said first side comprises a plurality of fins thereon, and said second side comprises at least an indentation facing towards said base;
a heat conductive metallic element, positioned in said indentation; and
a storage chamber, formed on either at least an inner sidewall of said indentation or on at least an outer surface of said heat conductive metallic element corresponding to said inner sidewall of said indentation; and
at least one jointing material disposed in said storage chamber.

2. The radiator for a heat sink device according to claim 1, wherein said base and heat conductive metallic element are comprised a same metal.

3. The radiator for a heat sink device according to claim 1, wherein said base and heat conductive metallic element are comprised of different metal.

4. The radiator for a heat sink device according to claim 2, wherein said metal is selected from a group consisting of gold, silver, copper, aluminum or alloys thereof.

5. The radiator for a heat sink device according to claim 1, wherein said jointing material comprises a heat conductive jointing material.

6. The radiator for a heat sink device according to claim 1, wherein said jointing material comprises solid tin, liquefied tin or tin paste.

7. The radiator for a heat sink device according to claim 1, wherein said indentation comprises a corrugated surface at an inner side thereof.

8. The radiator for a heat sink device according to claim 1, wherein said storage chamber comprises a corrugated surface.

9. The radiator for a heat sink device according to claim 1, wherein said heat conductive metallic element comprises a corrugated surface corresponding to said indentation.

10. The radiator for a heat sink device according to claim 1, wherein said indentation is connected to a flange of said base.

11. The radiator for a heat sink device according to claim 1, wherein said indentation is not connected to a flange of said base.
